(19) United States
(12) Patent Application Publication
(10) Pub. No.: US 2012/0026451 A1
(43) Pub. Date: Feb. 2, 2012

(54) TUNABLE LIQUID CRYSTAL LENS WITH SINGLE SIDED CONTACTS

(75) Inventor: Michael J. NYSTROM, San Jose, CA (US)

(73) Assignee: LENSVECTOR INC., Mountain View, CA (US)

(21) Appl. No.: 13/193,919

(22) Filed: Jul. 29, 2011

Related U.S. Application Data
(60) Provisional application No. 61/368,863, filed on Jul. 29, 2010.

(51) Int. Cl. G02F 1/13; H05K 13/00

(52) U.S. Cl. 349/200; 29/592.1

(57) ABSTRACT

A tunable liquid crystal lens device is provided that uses a number of conductive elements and external contacts all located along a common side of a device housing. The device may include planar electrodes, a patterned electrode, a heating element and a sensor, which may be in different layers of the device. The device is produced as part of an array of such devices and, in addition to the devices in the array, a plurality of electrical conductive strips are used to provide high conductivity connection to conductive layers in each of the devices, thereby allowing simultaneous testing of the devices in the array.

### REFERENCE TO RELATED APPLICATIONS

This application claims priority from U.S. Provisional Application U.S. 61/368,863 filed Jul. 29, 2010, which is incorporated herein by reference.

### FIELD OF THE INVENTION

This invention relates generally to the field of liquid crystal optical devices and, more particularly, to tunable liquid crystal lenses.

### BACKGROUND

Tunable liquid crystal (LC) optical devices, such as lenses, beam steering devices and shutters are known in the art. Typically, these devices use a spatially modified electric field generated by electrodes within the device. These electrodes require electrical connections to allow contact with external elements. Other electrical components may also be included within some of these devices, which may likewise require external electrical connections. Different package designs may be used to provide a device which is appropriately compact and which may be easily integrated into an external system.

### SUMMARY

In accordance with the proposed solution, a liquid crystal lens is provided that comprises a liquid crystal layer, a plurality of conductive elements, such as electrodes, and a surrounding housing. The device makes use of contacts on an exterior of the housing, each of which are in electrical communication with at least one of the conductive elements and which are positioned adjacent to one another in a first region of the housing. In an exemplary embodiment of the proposed solution, the contacts are all positioned along one side of the housing, simplifying the electrical connection of the device to external components. For example, the contacts may be arranged in a single row. The contacts may also be surface contacts, and vertical conductive portions may be provided that provide electrical connection between the surface contacts and the conductive elements in different layers of a lens device.

While electrodes are typically among the conductive elements in a liquid crystal lens device, other conductive elements may also be used. For example, a heater element may be used for increasing the operating temperature of the device, or an electrical sensor may be used to detect electrical properties of device components indicative of parameters such as temperature. Such elements are better described in co-pending commonly assigned U.S. provisional patent application 61/384,962 filed on Sep. 21, 2010 the subject matter of which is incorporated herein by reference. Other components requiring electrical connection may also be present.

In an exemplary embodiment of the proposed solution, the lens may be produced as part of a lens array manufactured using a wafer-scale process. In such a process, multiple lenses are constructed using the same wafer level layers, and are then singulated to form individual lens devices. The layers of the array correspond to layers in each of the resulting lens devices. During fabrication of the array, conductive bands may be applied to a substrate in a first layer, each band corresponding to a different row (column) of lenses in the array, and each extending across all of the individual devices of its respective row (column) such that simultaneous electrical contact may be made to all of the devices in that row (column). When the individual devices are singulated, the separated portions of a conductive band may function as electrodes for each of the lens devices. Conductive busbars that run perpendicular to the conductive bands may also be applied to the first layer during the wafer level fabrication, and make electrical contact with the conductive bands. These busbars provide a common connection point at either end of the conductive bands to allow a single testing signal to be applied simultaneously to all of the bands for testing the devices of the array. It is also possible to use a second set of conductive bands in the same layer that separate the columns (rows) of the individual lens devices and make contact with the first set of conductive bands.

In one embodiment of the proposed solution, a second layer of the array includes secondary, non-planar electrodes that work in concert with the planar electrodes of the first layer during operation of the singulated liquid crystal lenses. Each of the non-planar electrode devices is associated with a different one of the tunable lens devices and, together with its corresponding planar electrode, will generate an electric field for changing the optical properties of the liquid crystal layer of its respective device. The second layer can include conductive bands that each interconnect the secondary electrodes of a different one of the rows (columns) of devices in the array. In this embodiment, individual devices of the array may be tested during the wafer stage by selectively applying a drive signal between one or more conductive bands of the first layer and one or more conductive bands of the second layer. The result of this selective application is to provide a signal between the planar and non-planar electrodes of a single device, and to thereby change the optical properties of the liquid crystal layer for only one isolated device of the array.

### BRIEF DESCRIPTION OF THE DRAWINGS

The invention will be better understood by way of the following detailed description of embodiments of the invention with reference to the appended drawings, in which:

FIG. 1 is a schematic top view of a tunable liquid crystal lens device structure according to the proposed solution;

FIG. 2 is a schematic top view of a wafer-level array of tunable liquid crystal lens devices prior to their singulation into individual components;

FIG. 3 is a schematic, perspective exploded view of the structure shown in FIG. 2, showing the individual layers of the array;

FIG. 3A is a schematic, perspective exploded view of a structure similar to that of FIG. 3, but for which testing of the tunable liquid crystal lens devices may be done one at a time in the wafer stage;

FIG. 4A is a schematic perspective view of a singulated tunable liquid crystal device according to the proposed solution;

FIG. 4B is a schematic perspective view of the singulated tunable liquid crystal device with vertical contacts in place between internal elements and contact pads on a base of the device; and

FIG. 4C is a schematic bottom view of the singulated tunable liquid crystal device of FIG. 4B showing the arrangement of the contact pads on the bottom of the device.

### DETAILED DESCRIPTION

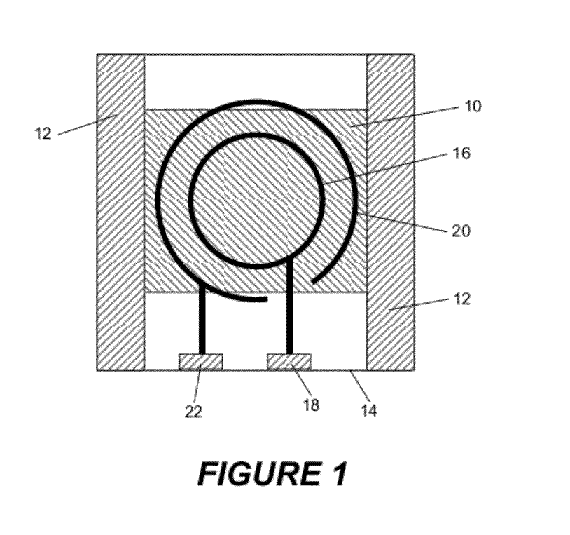

FIG. 1 is a top, schematic view of a tunable liquid crystal lens for which all electrical contact to the lens may be made along a single side of the device. In this embodiment, the lens includes two liquid crystal layers that are controlled by an electric field to form the desired lens configuration. The electric field is generated by electrodes to which a drive signal is connected. The electrodes include two planar electrodes and one centralized, hole-patterned control electrode. In this embodiment, heating and temperature sensing elements are also provided.

In the figure, the location of certain components in a horizontal dimension of the device is shown relative to the contact points. The planar electrodes 10 are in electrical contact with conductive strips 12 (highly conductive bands), each of which runs along an opposite edge of the (device layered) structure, thereby forming two contact points along the contact side 14 of the device. The control electrode 16 is, as discussed below, located between the planar electrodes 10 in a vertical dimension of the device, and has a contact point 18 along the contact side 14 of the device. A conductive sensor 20 is also provided, and has an electrical contact 22 along the contact side. The control structure 16/20 is better described in co-pending commonly assigned U.S. provisional patent application 61/384,962 filed on Sep. 21, 2010 the subject matter of which is incorporated herein by reference.

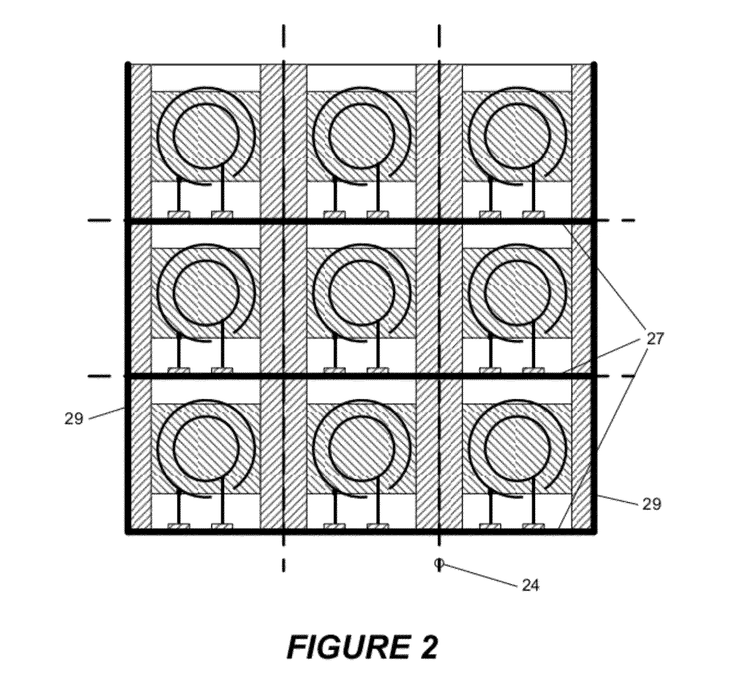

In an exemplary embodiment, the device of FIG. 1 is manufactured using a wafer scale process in which many such devices are formed simultaneously on a wafer scale structure, and are subsequently singulated to form the individual devices. This is demonstrated by the schematic top view of FIG. 2, which shows nine such devices formed from a single wafer structure. Those skilled in the art will understand that the number of devices shown in FIG. 2 is for descriptive purposes only and that the actual number of devices formed from a single wafer may, in fact, be much larger. FIG. 2 also shows dicing lines 24 (dashed lines) which indicate the lines along which dicing would be used to singulate the individual devices.

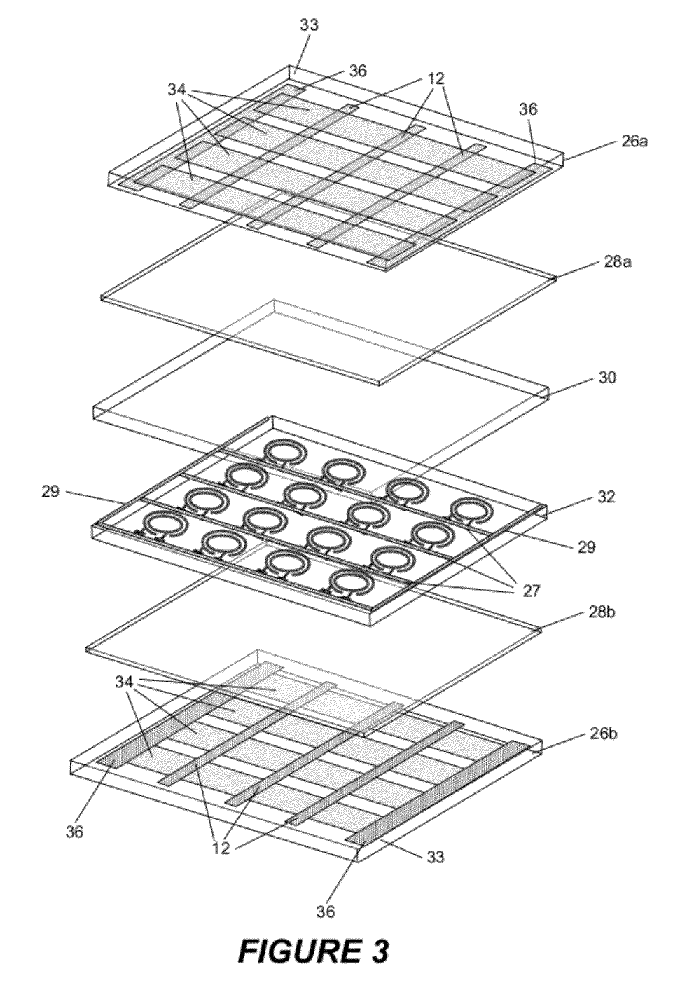

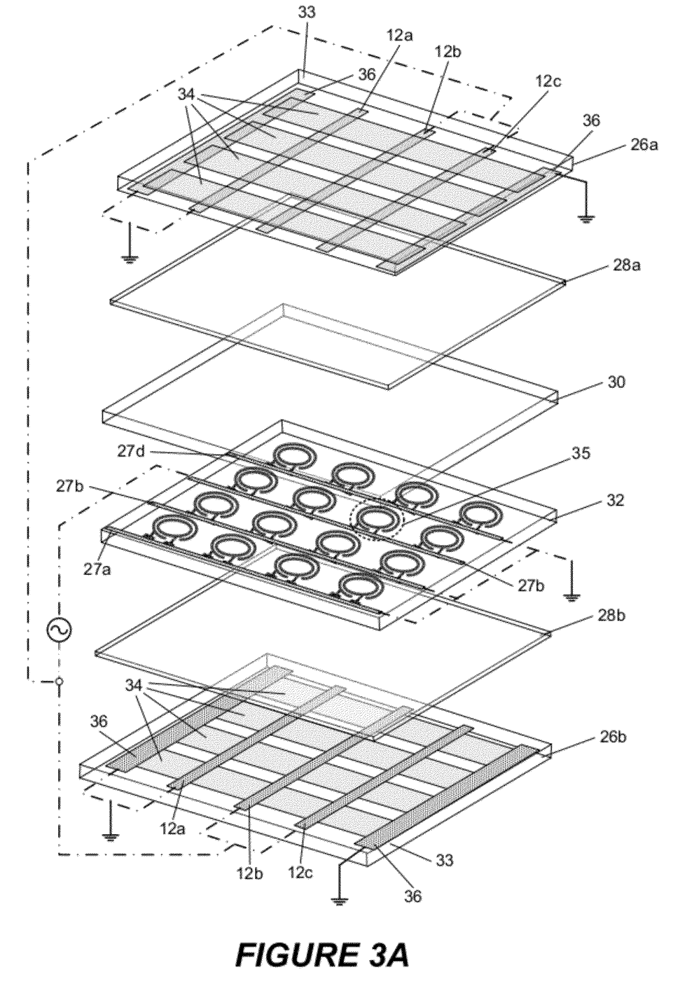

To better understand the layered structure of the liquid crystal lenses described herein, FIG. 3 shows a schematic, perspective view of the layers of the device during wafer fabrication, the layers being depicted in an exploded view. These layers include top and bottom planar electrode layers 26a, 26b, liquid crystals 28a, 28b, glass substrate 30 and control layer 32. Each of the planar electrode layers includes a glass substrate 33 and bands 34 of electrode material, each of which provides one planar electrode for each of the devices in the row corresponding to that band 34. In this embodiment, the electrode material is index matched indium tin oxide, and is deposited with a relatively small thickness (e.g., less that 100 nm). Also deposited on the substrates 26a, 26b are highly conductive strips 12, which provide electrical contact to the bands 34 and, after singulation, provide conductive paths for the planar electrodes 10 of the individual devices. These deposited strips 12 include busbars 36 that are deposited along two opposing edges of the array, and serve as primary contacts during array testing.

Also shown in FIG. 3 are strips 27 that are deposited on control layer 32 and serve to interconnect the contact points 18, 22 of each row of devices, thereby allowing common electrical connection to all of the devices of a row during array testing. Perpendicular conductors 29 are also deposited along the edges of the layer 32, perpendicular to, and in contact with, the strips 27. The perpendicular conductors 29 interconnect the strips 27 and allow common electrical connection to all of the components of the control layer. The strips 27 are also shown in FIG. 2, and may be removed during singulation of the devices. In general, the strips 12, 27 are of a highly conductive material, typically metal, and allow uniform contact to the planar electrodes of all of the devices of the array. In an exemplary embodiment, the strips 12, 27 and (busbars) 36 are deposited with a relatively large thickness (e.g., greater than 500 nm).

While the foregoing embodiment allows the simultaneous testing of all of the components in the wafer level array, an alternative embodiment may be used in which the individual devices may be individually addressed. An example of such an embodiment is shown in FIG. 3A, which is an exploded perspective view similar to that of FIG. 3. Those skilled in the art will understand that, while the figure is an exploded view, the testing actually takes place with all of the layers of the device in contact with each other. In the FIG. 3A embodiment, there are no perpendicular conductors along the edges of layer 32, and strips 27 of layer 32 are used along with strips 12 of layer 33 to power a desired one of the devices in the array. The application of different signal potentials to busbars 36 and strips 27 and 12 will provide power to the desired device. For example, to provide power to just the device 35 indicated in FIG. 3A, each of the planar electrode layers 26a, 26b has its busbars 36 and strips 12a connected to ground. Likewise, strips 27a, 27b and 27d of layer 32 are also connected to ground. A test signal may then be provided between strip 27c of the control layer 32 and strips 12b and 12c of each of planar electrode layers 26a, 26b. The presence of an electric potential between the control electrode and the planar electrode material of the device 35 thereby activates the liquid crystal lens for that device, the optical change in which is then detectable. Since the other strips 12a and the busbars 36 are connected to ground, the driver circuit must have sufficient capacity to drive the device and sustain a leakage current from the drive strips 12b, 12c to the next adjacent strips 12a or busbar 36 through the bands 34, which have a limited conductivity. By changing which of the strips 27 and which of the strips 12 or busbars 36 are connected to the signal source, individual devices may be powered and tested one at a time in the wafer stage.

Referring again to FIG. 3, each of the liquid crystals 28a, 28b is contained between one of the planar electrode layers 26a, 26b and an inner layer. On a first side of the device, the liquid crystal 28a is located between planar electrode layer 28a and glass substrate 30. The glass substrate 30 is an optically transparent glass material that provides support for the liquid crystal 28a. Each of the glass substrate 30 and the planar electrode layer 28a has an alignment layer coating (not shown), such as a polyimide, that provides the liquid crystal 28a with a desired pre-tilt, as is known in the art.

On a second side of the device, the liquid crystal 28b is contained between planar electrode layer 26b and control layer 32. The control layer 32 includes a glass substrate on which is deposited a frequency dependent material, that is, a material that is optically uniform, but which is electrically non-uniform for a predetermined set of electrical frequencies. This frequency dependent material behaves like a conductor at certain frequencies of the electric field, while appearing nonconductive at other frequencies. Thus, by adjusting the frequency of a drive signal applied to the electrodes, a spatial profile of the electric field may be modified. On top of the frequency dependent material the control electrode 16 and conductive sensor 20 are patterned. For each of the planar electrode layer 26b and the control layer 32, the side of the layer facing the liquid crystal 28b is coated with an alignment coating, such as polyimide. In addition, the planar electrodes may also serve as heater elements, and have a non-negligible finite resistance that results in resistive heating when an appropriate current is passed through them.

The wafer-level fabrication of the proposed solution produces devices that have all of their electrical contacts on a single side of the package. This allows the overall package to be smaller and simplifies the contact arrangement. The configuration of the metal strips 12, 27 and busbars 36 on the structure also improves wafer-level testing of the devices. If the only contact points were at the busbars 36 along the edges of the array, there would be a significant difference in how the devices near the interior of the array were driven as opposed to those along the edges. In the present embodiment, however, the metal strips 12 make contact with each of the planar electrodes, allowing them all to be driven in a relatively uniform manner during array level testing.

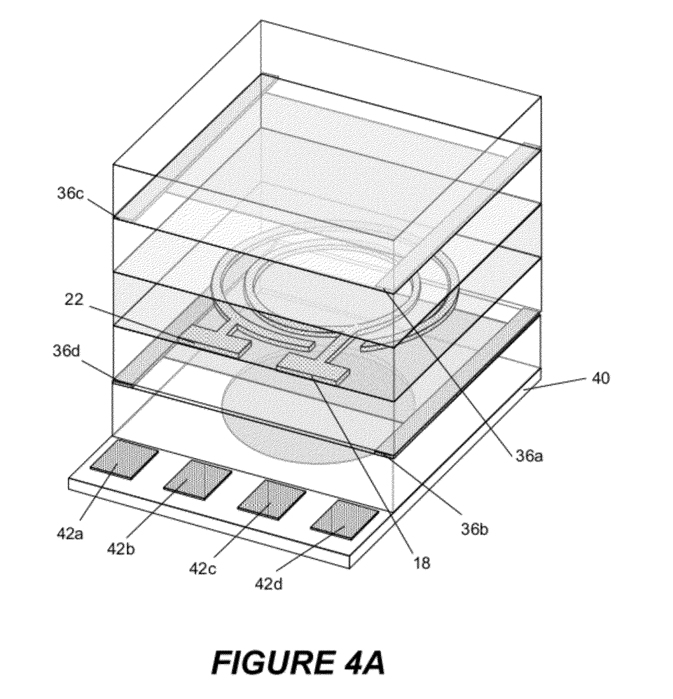

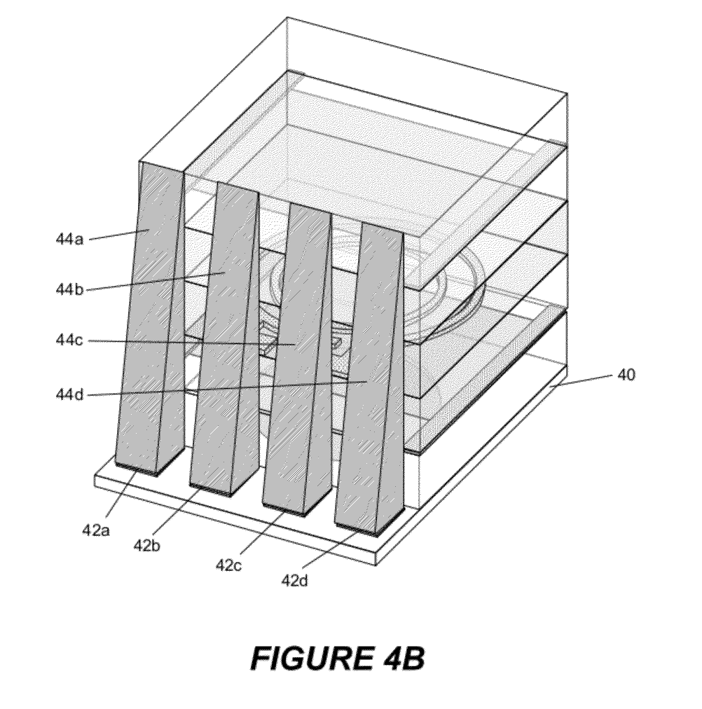

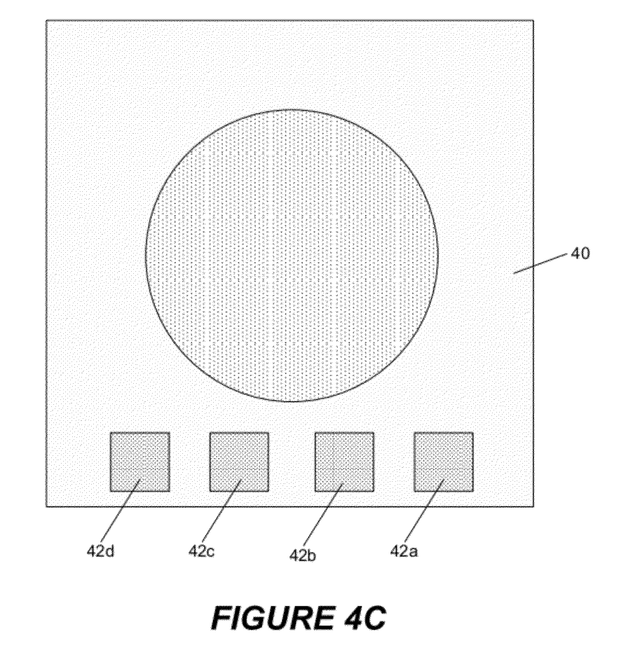

An example of a final device structure according to the present embodiment is shown in FIGS. 4A-4C. As shown in FIG. 4A, a package base 40 has a hole in the center to allow light to pass through it, and provides support for the other component layers. The base 40 also has contact pads 42a-42d that allow for easy electrical contact to the device. The different layers of the device have their contact points all along the same side of the device. Thus, the busbars 36a, 36b, 36c, 36d all have a contact edge at the front of the device. Likewise, electrical contacts 18 and 22 for the control electrode 16 and conductive sensor 20, respectively, are located at the same side. However, each of these contacts is at a different relative height along the front side of the device (package).

FIG. 4B shows the device structure (package) of FIG. 4A with full package contacts 44a-44d in place. Each of the full contacts 44a-44d makes contact, respectively, with one of the contact pads 42a-42d and extends vertically to make an electrical connection with the appropriate device contacts. Thus, contact 44a provides an electrical path between the contact pad 42a and the busbars 36c, 36d, contact 44b provides an electrical path between contact pad 42b and conductive sensor contact 22, contact 44c provides an electrical path between contact pad 44c and control electrode contact 18, and contact 44d provides an electrical path between contact pad 42d and busbars 36a, 36b.

It is understood that providing an electrical path between busbars 36c and 36d via contact 44a and between busbars 36a and 36b via contact 44d corresponds to the device drive mode illustrated in FIG. 3A wherein the control ring electrode 16 is driven with respect to planar electrodes 10 shown in FIG. 1 planar electrodes 10 which are driven at the same potential. The invention is not limited to the connectivity illustrated in FIG. 4B, differently configured contacts 44a and 44d can be employed to drive each top and bottom planar electrode 10 at a different potential via corresponding separate contact pads 42a and 42d, for example to account for differences in top and bottom liquid crystal layers 28a and 28b. The invention is not limited to the device illustrated in FIG. 4A which shows a single device with busbars 36 on both sides, a device singulated from a wafer having multiple devices thereon would have either strips 12 on both sides or strips 12 and busbars 36 on opposite sides.

The contact pads 42a-42d extend through the base 40 of the device (package) such that they are accessible on the other side of the base 40. Thus, as shown in FIG. 4C, when the package is fully enclosed in its exterior housing, the bottom of the device provides a simple set of surface contacts for connecting the lens to an appropriate device. The contact pads 42a-42d are easily accessible on the underside of the base 40. In this way, making contact with the conductive elements of the device may be achieved with relatively simple connections along just one side of the device and the device benefits from increased compactness. As shown, the central portion of the base also has a circular opening to allow the transmission of light therethrough. It should be noted that, while light will pass through the center of the lens structure, the orientation of the device relative to the direction of the light may be either sense, as the application requires. That is, light may pass through the rest of the device before passing through the base 40, or the base 40 may face the direction of the incoming light, such that light passes through it before the rest of the structure.

Regarding base 40, in the above reference has been made to a package base 40 and to the device package being fully enclosed in its exterior housing particularly with reference to FIGS. 4A, 4B and 4C.

As mentioned hereinabove, devices can have different package designs intended for integration into different external systems providing a corresponding form factor. In some embodiments the devices are required to be compact in general, in other embodiments the devices are required to be flat, while in other embodiments the devices are required to be slender.

In the context of the tunable liquid crystal lens devices presented herein, integration into external systems generally requires mechanical integration as well electrical integration.

Mechanical integration aspects concern providing sufficient structure to integrate the device into an external system including, but not limited to: positioning and orienting the devices with respect to the overall external system. As well mechanical integration aspects can also relate to structural integrity of the overall external system and mechanical protection of the device from environmental factors such as but not limited to shock and vibration.

Accordingly, the (package) base 40 can be shaped to provide form factors which enable mechanical device integration for example into a barrel assembly, a lens assembly, etc. The hole on the base 40 can be positioned with respect to the edges of base 40 to locate the optical axis of the device, while for example a pattern of notches or a pattern of holes (not shown) in the base 40 can dictate a specific orientation in mechanically integrating the device into the external system.

It is appreciated that positioning and orienting aspects are not limited to the (package) base 40. It is appreciated that (package) base 40 can be part of an overall package into which the device is provided for integration into external systems, base 40 acting as an interposer. The base 40 can by itself provide such a package, however the invention is intended to include other types of packaging such as, but not limited to: a barrel assembly, a lens assembly, an encasing material (resin), a mould, a coating, etc. In some embodiments base 40 is oversized with respect to the device to enable mechanical integration.

Electrical integration aspects concern providing sufficient structure to electrically interconnect the device to the external system including, but not limited to: powering, conditioning and driving the device. Powering and driving aspects relate to the actuation of the device within the overall system into which it is integrated, whereas conditioning aspect can relate to providing the environmental conditions (for example temperature control) for the device to operate as well to providing protection for example from: electrical shock, thermal shock, static electricity discharges, over-currents, under-currents, capacitive/inductive coupling, etc. and/or electrical shielding.

Accordingly, the (package) base 40 can be configured act as an electrical interconnect between the device and the external system into which the device is integrated, defining and simplifying electrical interconnection between the device and the external system.

It is appreciated that protection for example from: electrical shock, thermal shock, control of capacitive/inductive coupling, etc. and/or electrical shielding can be provided by other than the (package) base 40. It is appreciated that (package) base 40 can be part of an overall package into which the device is provided for integration into external systems, base 40 acting as an interposer. The base 40 can by itself provide such a package, however the invention is intended to include other types of packaging such as, but not limited to: a barrel assembly, a lens assembly, an encasing material (resin), a mould, a coating, etc. In some embodiments base 40 is oversized with respect to the device to enable electrical integration. For example the base 40, besides contact pads 42a-d, can also include shunt resistors for example to control over-currents, static electricity discharge etc., and signal conditioning electrical components to provide protection from: under-currents, capacitive/inductive coupling, etc., whereas the overall packaging can be configure to provide thermal shielding, thermal dissipation, capacitive/inductive coupling, etc. For example, the overall packaging can contain Zinc oxide thermal paste for temperature control, or invar for electrical shielding.

It is appreciated then that the device being an optical device, such as a tunable liquid crystal lens device cannot be totally encased in (opaque) packaging. While the base 40 is integrated into the stack of the singulated device, the base 40 and packaging can form part of the device housing together with other components of the device such as, but not limited to glass substrates 33 which provide an open optical path through the device. As such the housing includes the base, any packaging and components providing optical access to the device. In some embodiments, housing/packaging components can be optically transparent and/or provide optical conditioning, for example part of the housing/packaging can be made from a transparent material configured have an optical power (lenticular, graduated index lens, etc.) For clarity, in some embodiments the housing is the base 40.

While the invention has been shown and described with referenced to preferred embodiments thereof, it will be recognized by those skilled in the art that various changes in form and detail may be made therein without departing from the spirit and scope of the invention as defined by the appended claims.

1. A liquid crystal lens structure comprising:
a liquid crystal layer;
a plurality of conductive elements;
a housing; and
a plurality of contacts on an exterior of the housing, each of the contacts being in electrical communication with at least one of the conductive elements, the contacts being adjacent to one another in a first predetermined region of the housing.

2. A liquid crystal lens structure according to claim 1 wherein the plurality of conductive elements comprises an electrode.

3. A liquid crystal lens structure according to claim 1 wherein the plurality of conductive elements comprises a heater element.

4. A liquid crystal lens structure according to claim 1 wherein the plurality of conductive elements comprises an electrical sensor.

5. A liquid crystal lens structure according to claim 1 wherein the plurality of contacts are arranged in a row along a first side of the housing.

6. A liquid crystal lens structure according to claim 1 wherein the lens is manufactured using a wafer-scale process in which a plurality of said lenses are constructed as part of an array that is subsequently singulated to form individual lenses, and wherein each of a plurality of layers of the array corresponds to a layer in each of the lenses.

7. A liquid crystal lens structure according to claim 6 wherein the layers of the array include at least one layer with conductive bands each of which corresponds to a different row of lenses in the array, and each of which extends across all of the individual devices of its respective row such that simultaneous electrical contact may be made to all of the devices in that row.

8. A liquid crystal lens structure according to claim 7 wherein each of the bands comprises a conductive material that, when divided by singulation, forms planar electrodes in the individual devices.

9. A liquid crystal lens structure according to claim 8 wherein the conductive bands are each in electrical communication with conductive busbars that run in a direction perpendicular to the primary direction of the bands, and each of which resides along an opposing edge of the array, the busbars providing a common connection point at either end of the conductive bands to allow a single testing signal to be applied simultaneously to all of the bands.

10. A liquid crystal lens structure according to claim 8 wherein the conductive bands are a first set of conductive bands, and wherein the same layer of the array further comprises a second set of conductive bands that run perpendicular to the first set of bands and separate each column of lenses in the array, the second set of conductive bands being in electrical contact with the first set of conductive bands.

11. A liquid crystal lens structure according to claim 10 wherein the layer of the array containing the first and second set of conductive bands is a first layer, and wherein the array further comprises a second layer within which a plurality of secondary electrodes are located, each secondary electrode being associated with a different one of the devices, and wherein the second layer has a plurality of conductive pathways, each of which makes electrical contact with a plurality of the secondary electrodes.

12. A liquid crystal lens structure according to claim 11 wherein each of the conductive pathways makes electrical contact with each of the secondary electrodes along one of the rows of said devices, and wherein providing an electrical signal between at least one of the conductive pathways and at least one of said second set of conductive bands results in the generation of an electric field in each of a plurality of said devices that creates a detectable change in the optical properties of the liquid crystal layer of those devices.

13. A liquid crystal lens structure according to claim 12 wherein an application of an electrical signal to a certain combination of said conductive pathways and certain bands of said second set of conductive bands results in an electric field being generated only at the position of one of said devices.

14. A liquid crystal lens according to claim 1 wherein the plurality of conductive elements of the lens reside in different layers of the lens, and wherein the lens further comprises vertical conductive portions along one side of the lens that provide electrical communication between the contacts on the exterior of the housing and the conductive elements in the different layers.

15. A multilayer liquid crystal lens array having a plurality of liquid crystal lenses that may be singulated into individual lens devices, the array comprising:
a liquid crystal layer that, when the individual lens devices are singulated, is divided into a plurality of liquid crystal layers each of which corresponds to a different one of the lens devices;
a plurality of conductive layers that, when the individual lens devices are singulated, are divided into a plurality of device-specific conductive layer sets, each set of device-specific conductive layers being part of a different one of the lens devices; and
high conductivity electrical paths that, for each conductive layer, make direct electrical contact with each portion of that conductive layer that corresponds to a different one of the lenses, such that a common electric signal may be applied to each of said portions of a conductive layer via a single connection to a corresponding high conductivity electrical path.

16. A method of manufacturing a liquid crystal lens device, the method comprising:
providing a liquid crystal layer;
locating a plurality of conductive elements in proximity to the liquid crystal layer;
surrounding the liquid crystal layer and the plurality of conductive elements with a housing; and
locating a plurality of electrical contacts on an exterior of the housing, each of the contacts being in electrical communication with at least one of the conductive elements, the contacts being adjacent to one another in a first predetermined region of the housing.

17. A method according to claim 16 wherein the plurality of conductive elements comprises an electrode.

18. A method according to claim 16 wherein the plurality of conductive elements comprises a heater element.

19. A method according to claim 16 wherein the plurality of conductive elements comprises an electrical sensor.

20. A method according to claim 16 wherein locating a plurality of electrical contacts on an exterior of the housing comprises arranging the contacts in a row along a first side of the housing.

21. A method according to claim 16 further comprising manufacturing the device using a wafer-scale process in which a plurality of said lenses are constructed as part of an array that is subsequently singulated to form individual lenses, and wherein each of a plurality of layers of the array correspond to layers in each of the lenses.

22. A method according to claim 21 wherein the layers of the array include at least one layer with conductive bands each of which corresponds to a different row of lenses in the array, and each of which extends across all of the individual devices of its respective row such that simultaneous electrical contact may be made to all of the devices in that row.

23. A method according to claim 22 wherein each of the bands comprises a conductive material that, when divided by singulation, functions as electrodes in the individual devices.

24. A method according to claim 22 wherein the conductive bands are each in electrical communication with conductive busbars that run in a direction perpendicular to the primary direction of the bands, and each of which resides along an opposing edge of the array, the busbars providing a common connection point at either end of the conductive bands to allow a single testing signal to be applied simultaneously to all of the bands.

25. A method according to claim 22 wherein the conductive bands are a first set of conductive bands, and wherein the same layer of the array further comprises a second set of conductive bands that run perpendicular to the first set of bands and separate each column of lenses in the array, the second set of conductive bands being in electrical contact with the first set of conductive bands.

26. A method according to claim 25 wherein the layer of the array containing the first and second set of conductive bands is a first layer, and wherein the array further comprises a second layer within which a plurality of secondary electrodes are located, each secondary electrode being associated with a different one of the devices, and wherein the second layer has a plurality of conductive pathways, each of which makes electrical contact with a plurality of the secondary electrodes.

27. A method according to claim 26 wherein each of the conductive pathways makes electrical contact with each of the secondary electrodes along one of the rows of said devices, and wherein the method further comprises testing the structure by providing an electrical signal between at least one of the conductive pathways and at least one of said second set of conductive bands to generate an electric field in each of a plurality of said devices so as to create a detectable change in the optical properties of the liquid crystal layers of said devices.

28. A method according to claim 27 further comprising testing an isolated device of the array by applying an electrical signal to a certain combination of said conductive pathways and certain bands of said second set of conductive bands to generate an electric field only at the position of said isolated device.

29. A method according to claim 16 wherein the plurality of conductive elements of the lens reside in different layers of the lens, and wherein the lens further comprises vertical conductive portions along one side of the lens that provide electrical communication between the contacts on the exterior of the housing and the conductive elements in the different layers.
